(19) United States
(12) Patent Application Publication
(10) Pub. No.: US 2018/0269219 A1
(43) Pub. Date: Sep. 20, 2018

(54) SEMICONDUCTOR MEMORY DEVICE

(71) Applicant: Toshiba Memory Corporation, Minato-ku (JP)

(72) Inventors: Sachiyo Ito, Kawasaki (JP); Ai Omodaka, Yokkaichi (JP); Tatsuhiro Oda, Yokohama (JP)

(73) Assignee: Toshiba Memory Corporation, Minato-ku (JP)

(21) Appl. No.: 15/788,869

(22) Filed: Oct. 20, 2017

(30) Foreign Application Priority Data
Mar. 14, 2017 (JP) 2017-048591

(51) Int. Cl. H01L 27/11565; H01L 27/11582; H01L 27/11575

(52) U.S. Cl. CPC H01L 27/11565; H01L 27/11575; H01L 27/11582

(57) ABSTRACT

According to an embodiment, a semiconductor memory device includes a substrate, a circuit portion, a stacked body, at least one columnar member, a device isolation portion, and at least one first support member. The columnar member is in contact with an interconnect layer, and includes a contact extending in a stacking direction of a plurality of electrode films in the stacked body. The device isolation portion is provided in the stacked body and extends in a first direction and the stacking direction. The first support member is provided in the stacked body, extends in the stacking direction, and is located on the device isolation portion in a second direction crossing the first direction and along the upper surface of the substrate.

### CROSS-REFERENCE TO RELATED APPLICATIONS

This application is based upon and claims the benefit of priority from Japanese Patent Application No.2017-048591, filed on Mar. 14, 2017; the entire contents of which are incorporated herein by reference.

### FIELD

Embodiments relate generally to a semiconductor memory device.

### BACKGROUND

In a semiconductor memory device having a three-dimensional structure, a stacked body in which an insulating film and an electrode film are alternately stacked is provided on a substrate, and a channel piercing the stacked body is provided. Then, a memory cell is formed at each of crossing portions between the electrode films and the channel. Further, in order to achieve higher integration, a control circuit which controls the memory cell is disposed between the substrate and the stacked body, and an electrical potential is supplied to the control circuit through a through-via in the stacked body. In such a semiconductor memory device, in the vicinity of the through-via, the structural strength of the stacked body is likely to be decreased, and there is a problem that the stacked body is deformed.

### BRIEF DESCRIPTION OF THE DRAWINGS

FIG. 1 is a plan view showing a semiconductor memory device according to a first embodiment;

FIG. 2A and FIG. 2B are sectional views taken along a line A1-A2 and a line B1-B2 of FIG. 1;

FIG. 3 is an enlarged view of a region A of FIG. 2A;

FIG. 4 is a plan view showing a part of the semiconductor memory device according to the first embodiment;

FIG. 5 is a sectional view taken along a line C1-C2 of FIG. 4;

FIG. 6 is a plan view showing a method for manufacturing the semiconductor memory device according to the first embodiment;

FIG. 7 is a plan view showing a method for manufacturing the semiconductor memory device according to the first embodiment;

FIG. 8 is a plan view showing a method for manufacturing the semiconductor memory device according to the first embodiment;

FIG. 9 is a plan view showing a method for manufacturing the semiconductor memory device according to the first embodiment; and

FIG. 10 is a plan view showing a method for manufacturing the semiconductor memory device according to the first embodiment.

### DETAILED DESCRIPTION

According to an embodiment, a semiconductor memory device includes a substrate, a circuit portion, a stacked body, at least one columnar member, a device isolation portion, and at least one first support member. The circuit portion is provided on the substrate, and includes an interconnect layer. The stacked body is provided on the circuit portion, and includes a plurality of electrode films which is separately stacked each other and extends in a first direction along an upper surface of the substrate. The columnar member is in contact with the interconnect layer, and includes a contact extending in a stacking direction of the plurality of electrode films in the stacked body. The device isolation portion is provided in the stacked body and extends in the first direction and the stacking direction. The first support member is provided in the stacked body, extends in the stacking direction, and is located on the device isolation portion in a second direction crossing the first direction and along the upper surface of the substrate.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

### First Embodiment

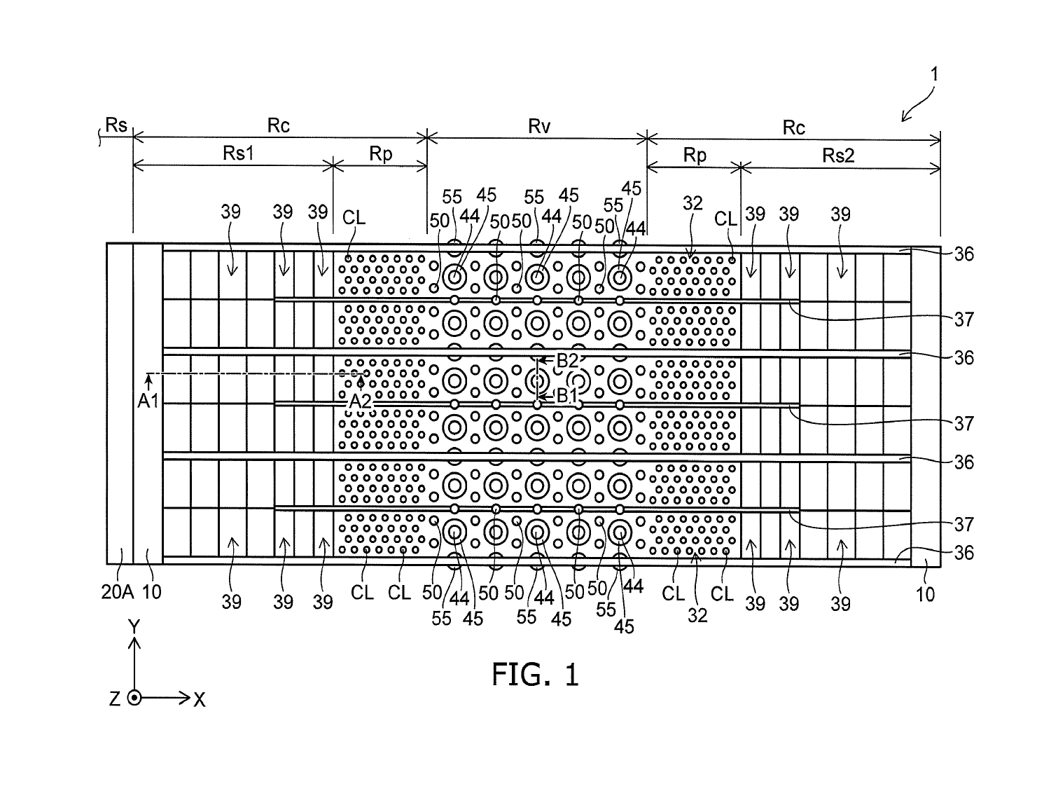

FIG. 1 is a plan view showing a semiconductor memory device 1.

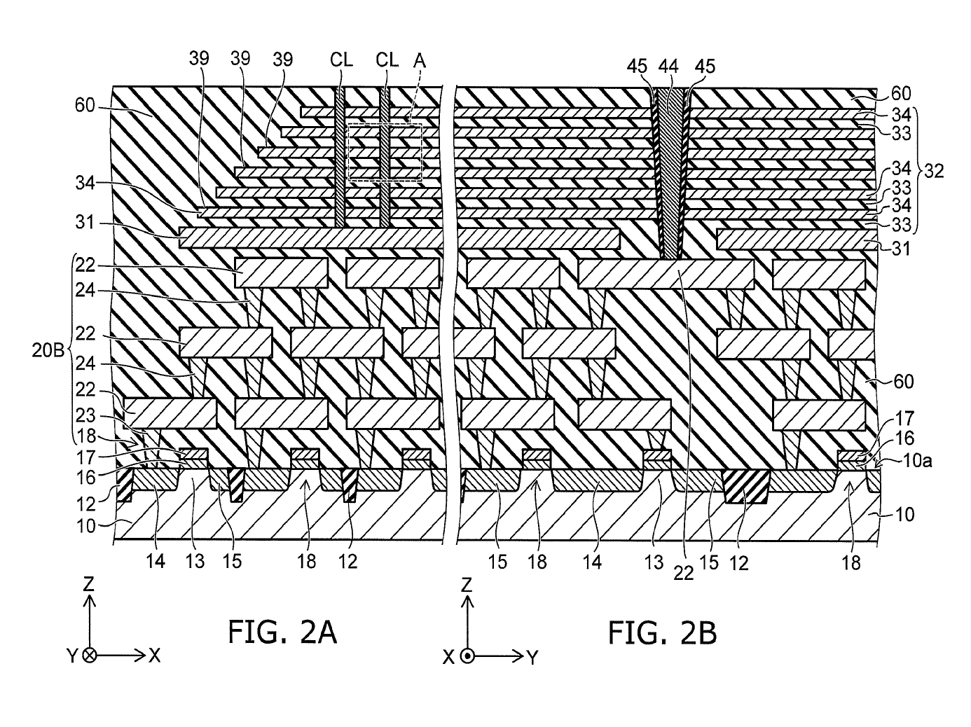

FIG. 2A and FIG. 2B are sectional views taken along a line A1-A2 and a line B1-B2 of FIG. 1, respectively.

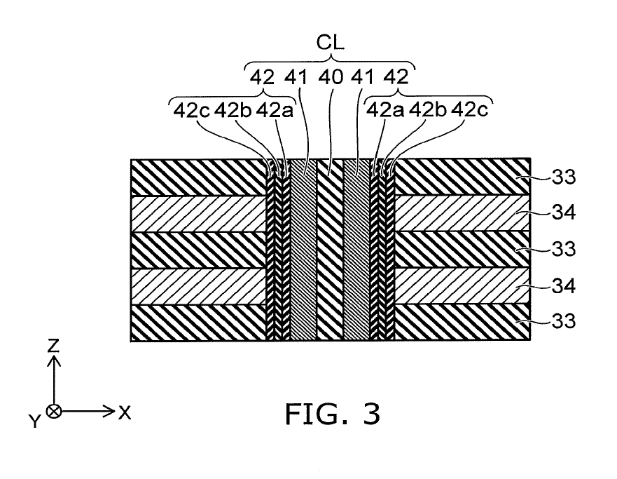

FIG. 3 is an enlarged view of a region A of FIG. 2A.

As shown in FIG. 1, FIG. 2A, and FIG. 2B, in the semiconductor memory device 1, a substrate 10 containing silicon (Si) or the like is provided. Hereinafter, in the specification, for the sake of convenience of description, an XYZ orthogonal coordinate system is adopted. Two directions parallel to an upper surface 10a of the substrate 10 and also orthogonal to each other are referred to as “X-direction” and “Y-direction”, and a direction perpendicular to the upper surface 10a is referred to as “Z-direction”.

As shown in FIG. 1, in the semiconductor memory device 1, a through-via region Rv, a cell region Rc, and a peripheral region Rs are provided.

In the through-via region Rv, a plurality of through-vias 44 (contacts) is provided.

The cell region Rc is located on both sides in the X-direction of the through-via region Rv. In the cell region Rc, a memory cell array including a plurality of memory cells is provided.

The peripheral region Rs is located in the periphery of the cell region Rc. In the peripheral region Rs, a control circuit 20A such as a row decoder is provided. For example, the control circuit 20A is located on one side in the X-direction of the cell region Rc.

As shown in FIG. 2A and FIG. 2B, in the cell region Rc and the through-via region Rv, an STI (Shallow Trench Isolation) 12 is selectively provided on an upper portion of the substrate 10. By the STI 12, the upper portion of the substrate 10 is divided into a plurality of semiconductor regions 13. In the semiconductor region 13, a source layer 14 and a drain layer 15 are provided. In an area on the substrate 10 and immediately above a region between the source layer 14 and the drain layer 15, a gate insulating film 16 and a gate electrode 17 are provided. According to this, on an upper surface 10a of the substrate 10, a plurality of field-effect transistors 18 is formed.

On the substrate 10, an interlayer insulating film 60 containing, for example, silicon oxide (SiO) is provided. In the interlayer insulating film 60, a plurality of interconnect layers 22 is provided. Between the substrate 10 and the lowermost layer of the interconnect layer 22, a contact 23 is connected. Between the interconnect layers 22 spaced from each other in the Z-direction, a via 24 is connected. By the transistor 18, the interconnect layer 22, the contact 23, and the via 24, a control circuit 20B such as a sense amplifier is constituted.

On the uppermost layer of the interconnect layer 22, a buried source line 31 is provided. The buried source line 31 is, for example, a two-layer film having a lower layer part containing tungsten (W) and an upper layer part containing silicon. The buried source line 31 is divided into a plurality of parts in the X-direction, and is disposed in the through-via region Rv and the cell region Rc. To the buried source line 31, an electrical potential is supplied from the control circuit 20B.

On the buried source line 31, the stacked body 32 is provided. In the stacked body 32, for example, an insulating film 33 containing silicon oxide and an electrode film 34 containing tungsten are alternately stacked along the Z-direction.

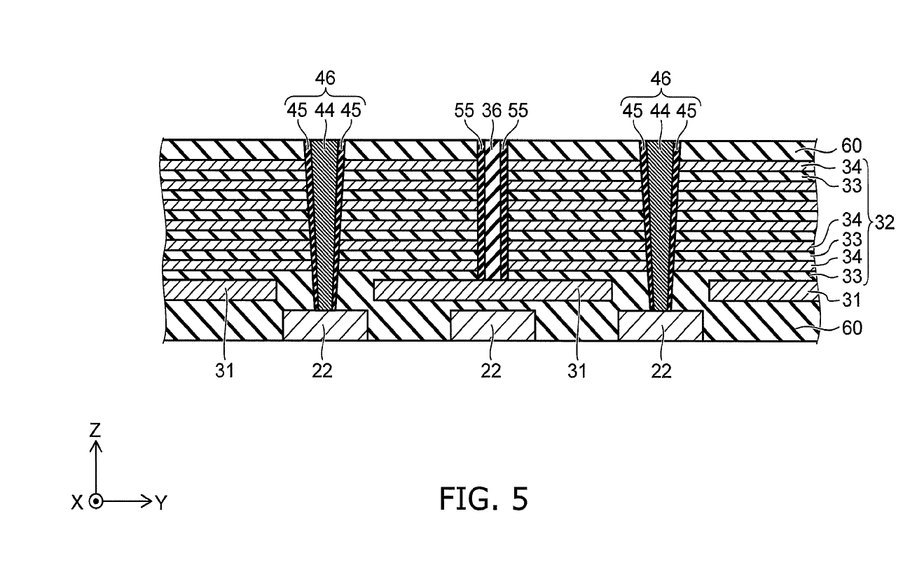

As shown in FIG. 1, in the stacked body 32, a plurality of device isolation portions 36 is provided. For example, the lower end of the device isolation portion 36 is in contact with the buried source line 31 (see FIG. 5). The shape of the device isolation portion 36 is a plate shape expanding along an XZ plane. By the device isolation portions 36, the stacked body 32 is divided into a plurality of parts in the Y-direction, and the shape of the electrode film 34 is in an interconnect shape extending in the X-direction.

In the device isolation portion 36, an interconnect portion connected to the buried source line 31 is provided as a portion of a source line. In this case, in the device isolation portion 36, the interconnect portion and an insulating film provided on both side surfaces of the interconnect portion are provided. The device isolation portion 36 may be constituted by an insulating film containing silicon oxide or the like.

Between the device isolation portions 36 adjacent to each other in the Y-direction, an insulating member 37 extending in the X-direction is provided. The insulating member 37 is located, for example, in the center between the device isolation portions 36 adjacent to each other in the Y-direction. The insulating member 37 is disposed in an upper portion of the stacked body 32, and divides each of one or more electrode films 34 from the above into two. The divided electrode film 34 functions as an upper select gate line. In the example shown in FIG. 1, the insulating member 37 divides three electrode films 34 from the above.

As shown in FIG. 1 and FIG. 2A, in the cell region Rc, a real staircase region Rs1, a pillar disposition region Rp, and a dummy staircase region Rs2 are provided, and are arranged in this order along the X-direction. That is, on both sides in the X-direction of the pillar disposition region Rp, the real staircase region Rs1 and the dummy staircase region Rs2 are disposed.

In the pillar disposition region Rp, a plurality of columnar portions CL extending in the Z-direction is provided in the stacked body 32. As shown in FIG. 1, the columnar portions CL are disposed in a plurality of rows, for example, four rows between the device isolation portion 36 and the insulating member 37.

As shown in FIG. 3, the columnar portion CL has an insulating core portion 40, a silicon pillar 41 (semiconductor pillar), and a memory film 42. The insulating core portion 40 contains, for example, silicon oxide. The silicon pillar 41 is provided in the periphery of the insulating core portion 40. The silicon pillar 41 contains, for example, silicon, and the shape thereof is a cylindrical shape in which a lower end portion is closed. In the silicon pillar 41, the lower end is connected to the buried source line 31, and the upper end reaches the upper surface of the stacked body 32.

The memory film 42 has a tunnel insulating film 42a, a charge storage film 42b, and a block insulating film 42c.

The tunnel insulating film 42a is provided on a side surface of the silicon pillar 41. The tunnel insulating film 42a contains, for example, silicon oxide.

The charge storage film 42b is provided on a side surface of the tunnel insulating film 42a. The charge storage film 42b is a film for storing electric charge, and contains, for example, silicon nitride (SiN).

The block insulating film 42c is provided on a side surface of the charge storage film 42b. The block insulating film 42c contains, for example, silicon oxide.

On the columnar portion CL, a plurality of bit lines extending in the Y-direction is provided, and the silicon pillar 41 of the columnar portion CL is connected to the bit line through a contact. Incidentally, in FIG. 1, constituent elements disposed above the stacked body 32 are not illustrated.

In the real staircase region Rs1 and the dummy staircase region Rs2, the shape of the stacked body 32 is a staircase shape in which a step 39 is formed in the electrode film 34. In the real staircase region Rs1, a contact (not shown) is provided in an area immediately above the step 39, and is connected to the electrode film 34 in which the step 39 is formed. The electrode film 34 is connected to the control circuit 20A through the contact. On the other hand, in the dummy staircase region Rs2, a contact connected to the electrode film 34 is not provided.

Next, constituent elements in the through-via region Rv will be described in detail.

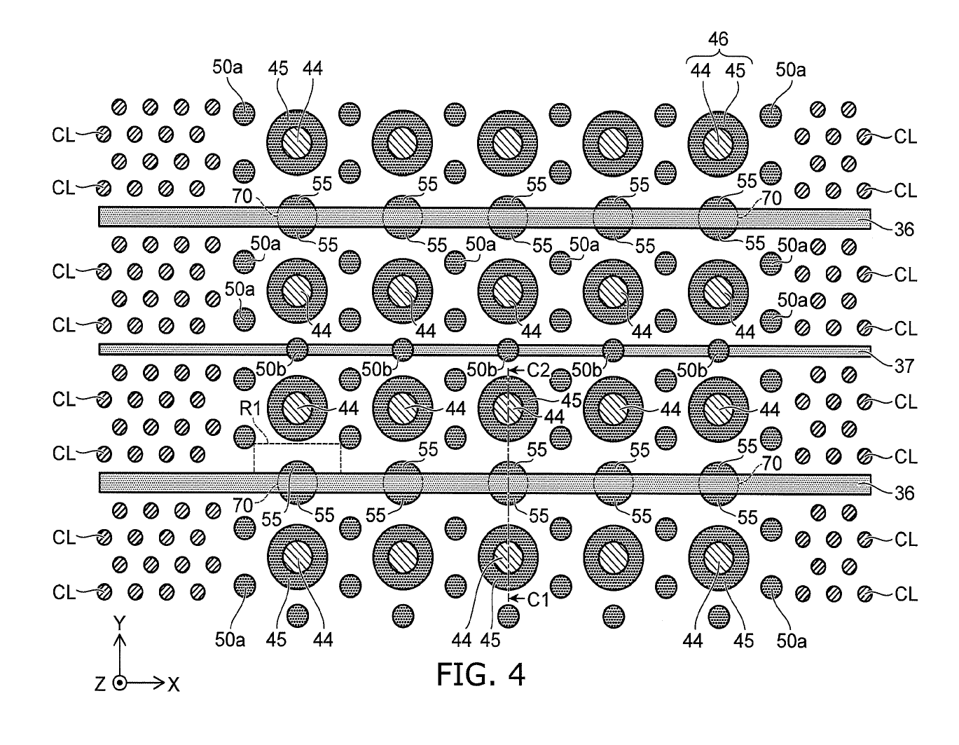

FIG. 4 is a plan view showing a part of the semiconductor memory device 1.

FIG. 5 is a sectional view taken along a line C1-C2 of FIG. 4.

FIG. 4 shows the through-via region Rv of FIG. 1 in an enlarged view, and FIG. 5 shows a section of the device isolation portion 36 located between the through-vias 44.

As shown in FIG. 4 and FIG. 5, in the through-via region Rv, the through-via 44 extends in the Z-direction and pierces the stacked body 32. The through-via 44 is constituted by, for example, a main body portion containing tungsten and a barrier metal layer containing titanium nitride (TiN) on a side surface and on a lower surface of the main body portion. For example, the shape of the through-via 44 is a circular column. In the through-via 44, the lower end is connected to the uppermost layer of the interconnect layer 22 in the control circuit 20B, and the upper end reaches the upper surface of the stacked body 32.

The through-via 44 is disposed along the X-direction and Y-direction between the device isolation portions 36. Here, the center of the through-via 44 corresponds to the center of the circle shown in FIG. 4 when the shape of the through-via 44 is a circular column.

On a side surface of the through-via 44, for example, an insulating film 45 containing silicon oxide is provided. The through-via 44 is insulated from the electrode film 34 by the insulating film 45. Further, the through-via 44 passes between parts of the buried source line 31, and is also spaced and insulated from the buried source line 31. Hereinafter, in the specification, the through-via 44 and the insulating film 45 are sometimes called “columnar member 46”.

On the through-via 44, an upper layer interconnect (not shown) is provided. The through-via 44 is connected to the upper layer interconnect. That is, the upper layer interconnect is connected to the interconnect layer 22 of the control circuit 20B through the through-via 44. This interconnect layer 22 is connected to the source layer 14, the drain layer 15, or the gate electrode 17 of the transistor 18. In this manner, in the control circuit 20B, a power supply potential or a signal potential is supplied through the upper layer interconnect and the through-via 44.

In the through-via region Rv, a plurality of support members 50 is provided. The support member 50 extends in the Z-direction and pierces the stacked body 32. The support member 50 contains, for example, silicon oxide. For example, the shape of the support member 50 is a circular column. For example, in the support member 50, the lower end is in contact with the buried source line 31, and the upper end reaches the upper surface of the stacked body 32.

The support member 50 has a support member 50a and a support member 50b.

The support members 50a are disposed in a plurality of rows, for example, two rows between the device isolation portion 36 and the insulating member 37. In this case, in the X-direction, some support members 50a are located between the columnar members 46, and the other support members 50a are located between the columnar portion CL and the columnar member 46.

Here, the center of the support member 50 corresponds to the center of the circle shown in FIG. 4 when the shape of the support member 50 is a circular column.

The support member 50b is disposed along the X-direction between the insulating members 37. Further, the support member 50b is located between the columnar members 46 in the Y-direction.

In the through-via region Rv, a plurality of support members 55 is provided. The support member 55 extends in the Z-direction and pierces the stacked body 32. The support member 55 contains, for example, silicon oxide. The support member 55 may contain polysilicon. The shape of the support member 55 is, for example, a columnar shape in which an arc is formed in a part. The shape of the support member 55 may be a prismatic column. For example, in the support member 55, the lower end is in contact with the buried source line 31, and the upper end reaches the upper surface of the stacked body 32.

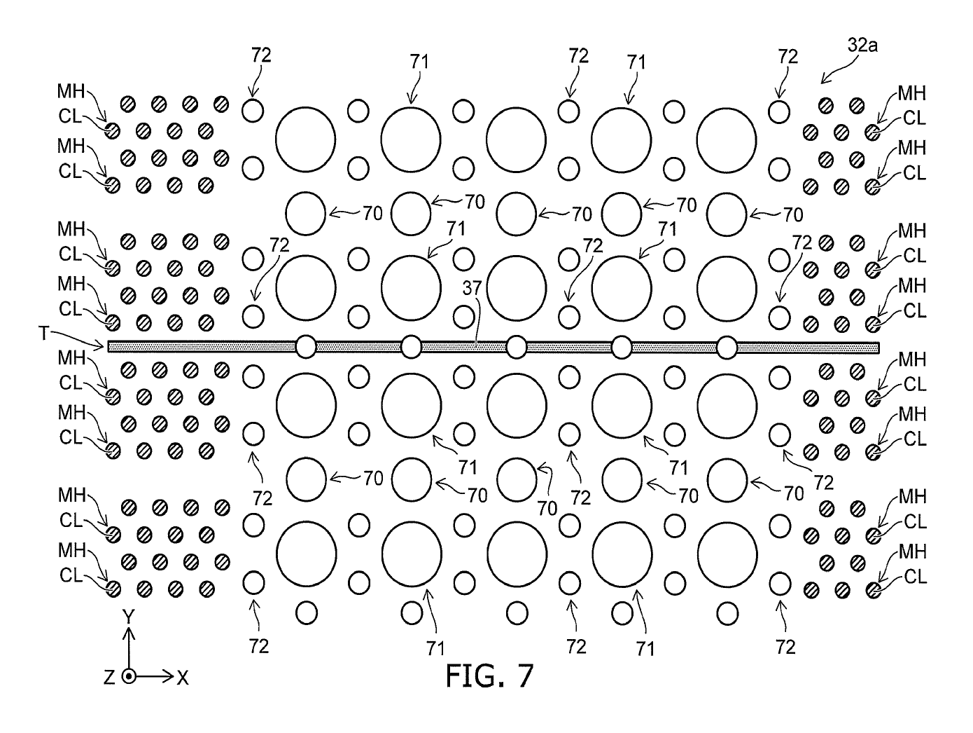

In the stacked body 32, a plurality of through-holes 70 (see FIG. 7) as indicated by the broken lines in FIG. 4 is formed, and the support member 55 is located so as to bury a part (a part on both ends in the Y-direction) of the through-hole 70. On the other hand, in the other part (a central part) of the through-hole 70, the device isolation portion 36 is buried. According to this, the support member 55 is located on both side surfaces in the Y-direction of the device isolation portion 36. In the example shown in FIG. 4, the support member 55 is located on both side surfaces in the Y-direction of the device isolation portion 36, but may be located on one side surface in the Y-direction.

The support member 55 is disposed along the X-direction. The support member 55 is located between the columnar members 46 in the Y-direction. That is, as shown in FIG. 4, the support member 55 is located in a region R1 surrounded by the device isolation portion 36, the columnar member 46, and the support member 50a in the through-via region Rv. The region R1 corresponds to a region in which none of the columnar member 46 and the support member 50 (support members 50a and 50b) are not provided.

For example, the shortest distance from an end portion of the support member 55 disposed in the X-direction to an end portion of the support member 55 adjacent thereto is desirably 150 nm or more and 600 nm or less.

Next, a method for manufacturing a semiconductor memory device according to the embodiment will be described.

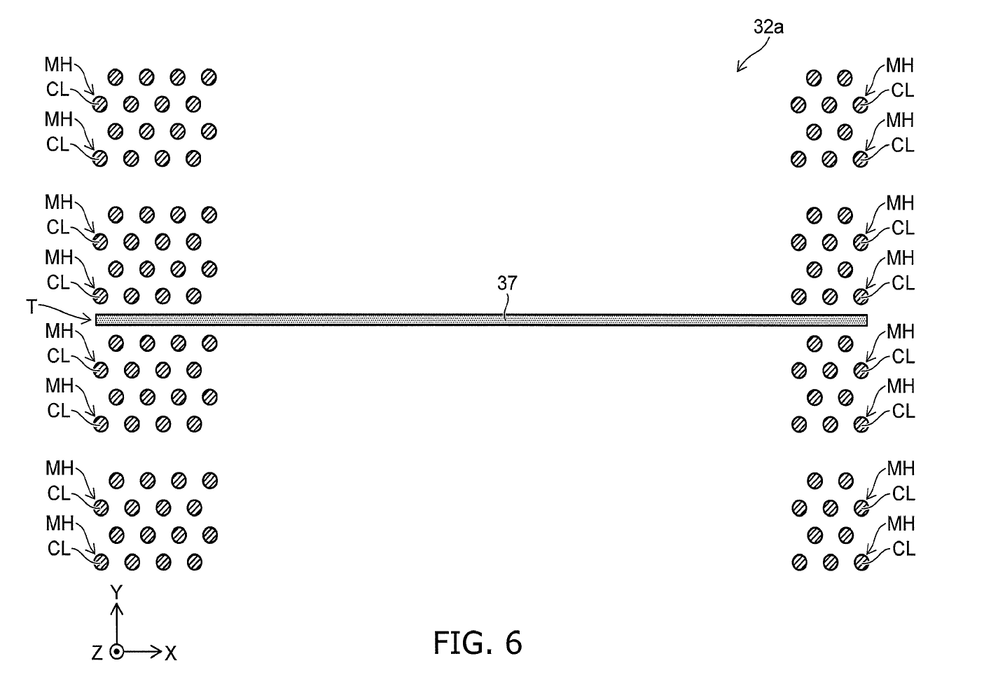

FIG. 6 to FIG. 10 are plan views showing a method for manufacturing a semiconductor memory device 1.

In FIG. 6 to FIG. 10, a process for forming a through-via region Rv of the semiconductor memory device 1 is shown. A region shown in FIG. 6 to FIG. 10 corresponds to the region shown in FIG. 4.

First, as shown in FIG. 6, on a substrate 10, a stacked body 32a in which an insulating film 33 and a sacrifice film are alternately stacked is formed. The sacrifice film is formed of, for example, a silicon nitride film. Subsequently, a memory hole MH is formed in the stacked body 32a, and thereafter, a memory film 42, a silicon pillar 41, and an insulating core portion 40 are sequentially formed in the memory hole MH. By doing this, a columnar portion CL is formed. Thereafter, a trench T is formed in the stacked body 32a, and then, an insulating member 37 is formed in the trench T.

Subsequently, as shown in FIG. 7, a plurality of through-holes 70, 71, and 72 are formed in the stacked body 32a by, for example, photolithography using a mask and an etching treatment such as RIE (Reactive Ion Etching). The shape of each of the through-holes 70, 71, and 72 when viewed from the Z-direction is, for example, a circular shape. For example, the diameter of the through-hole 70 is smaller than the diameter of the through-hole 71 and larger than the diameter of the through-hole 72.

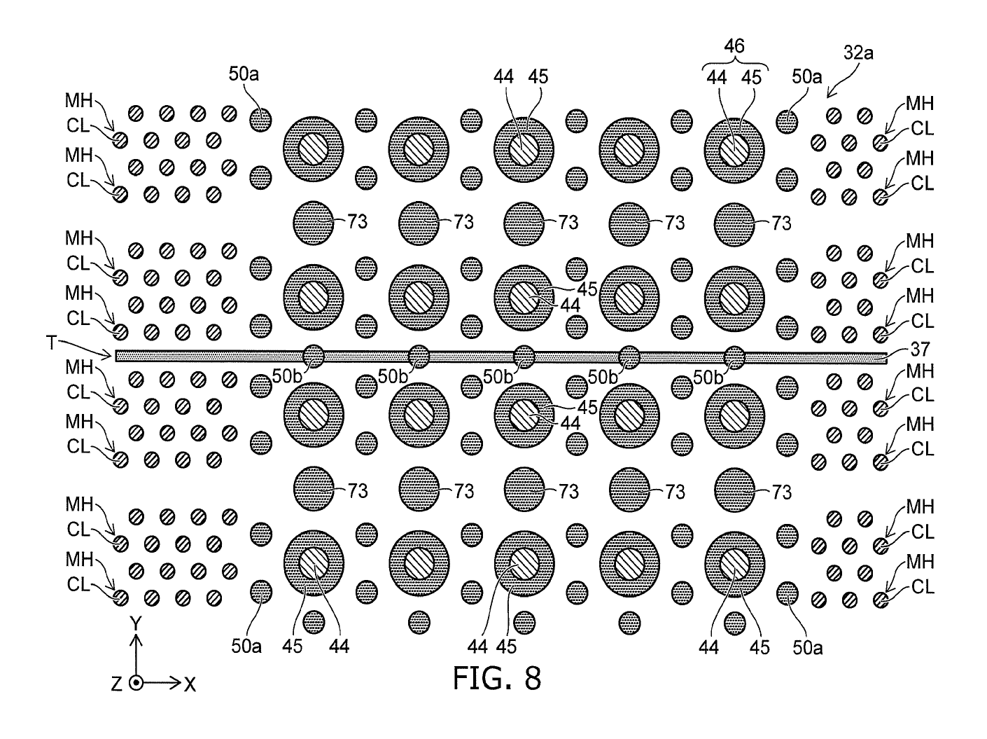

Subsequently, as shown in FIG. 8, for example, silicon oxide is buried in the through-holes 70, 71, and 72 by, for example, a CVD (Chemical Vapor Deposition) method. In the through-hole 70, an insulating film 73 is formed. A plurality of insulating films 73 is disposed in the X-direction. Further, an insulating film 45 is formed in the through-hole 71, and a support member 50 having a support member 50a and a support member 50b is formed in the through-hole 72.

Subsequently, a through-via 44 is formed in the through-hole 71 and on the insulating film 45. By doing this, a columnar member 46 having the through-via 44 and the insulating film 45 is formed.

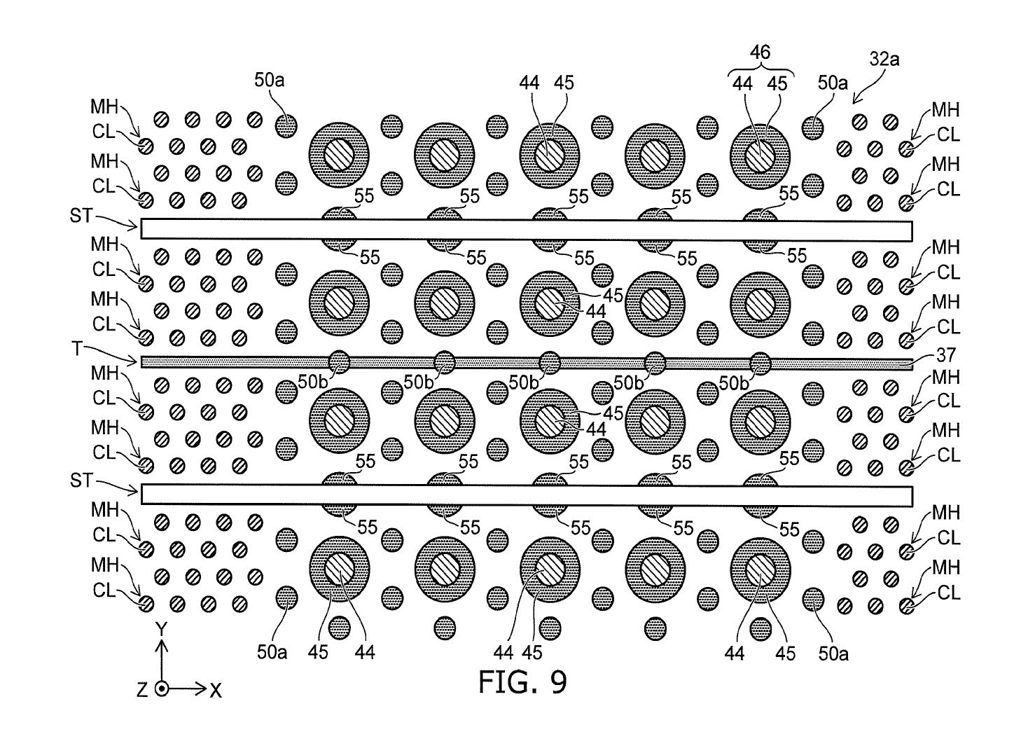

Subsequently, as shown in FIG. 9, by an etching treatment such as RIE, a plurality of slits ST extending in the X-direction and Z-direction is formed in the stacked body 32a. A portion of the insulating film 73 is removed so as to divide the insulating film 73 in the Y-direction by the formation of the slit ST. By doing this, a support member 55 is formed. The support member 55 is located on both side surfaces in the Y-direction of the slit ST.

Subsequently, by performing wet etching through the slit ST, the sacrifice film of the stacked body 32a is removed. In a space formed by removing the sacrifice film, an electrode film 34 is formed by depositing a metal such as tungsten through the slit ST. By doing this, a stacked body 32 is formed.

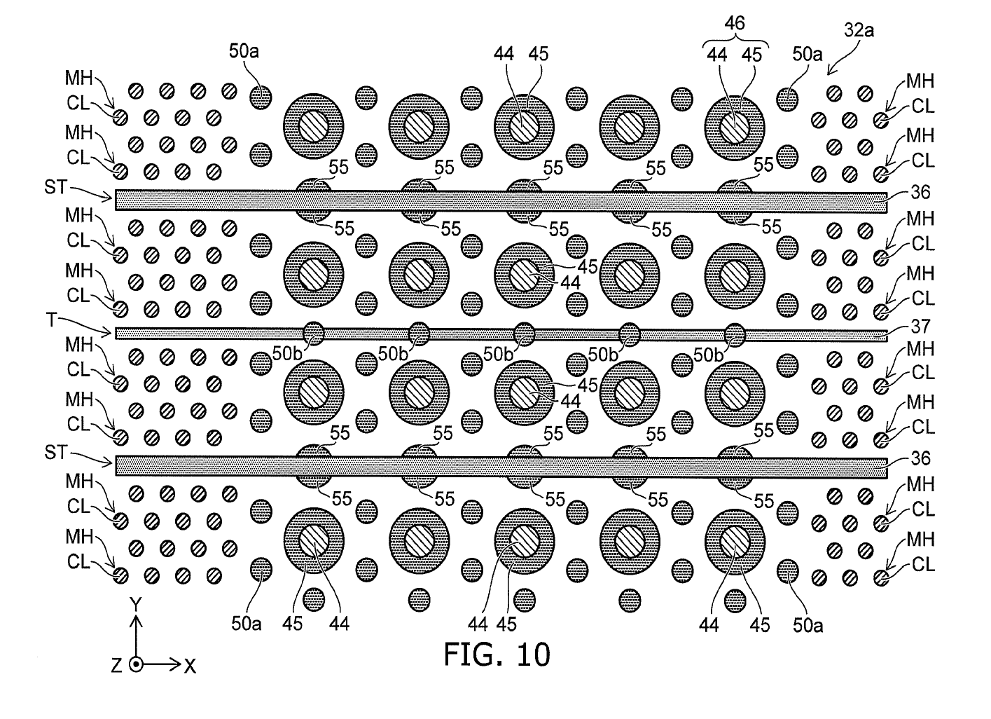

Subsequently, as shown in FIG. 10, for example, by a CVD method, a device isolation portion 36 is formed in the slit ST. On both side surfaces in the Y-direction of the device isolation portion 36, the support member 55 is located. In this manner, the semiconductor memory device 1 is manufactured.

Next, effects of the embodiment will be described.

In the semiconductor memory device 1 according to the embodiment, the support member 55 is provided in the through-via region Rv in which the through-via 44 is provided, and on both side surfaces in the Y-direction of the device isolation portion 36. By providing such a support member 55, the structural strength in the vicinity of the through-via 44 can be improved. According to this, deformation of the stacked body 32 can be suppressed.

Further, by providing the support member 55 in the region R1 of the through-via region Rv, the structural strength in the region R1 of the through-via region Rv is improved, and thus, deformation of the stacked body 32 can be further suppressed.

For example, in the process for removing the sacrifice film from the stacked body 32a through the slit ST as shown in FIG. 9, the inside of the space is washed and dried after removing the sacrifice film. In such washing and drying, surface tension occurs in the stacked body 32a, and therefore, the stacked body 32a is bent and deformed in some cases. As shown in FIG. 4, in the through-via region Rv, in the region R1 in which the through-via 44 and the support member 50 are not formed, the structural strength is decreased, and therefore, deformation of the stacked body 32a is likely to occur. There is a fear that by the deformation of the stacked body 32a, the electrode film 34 is bent and deformed, and a defect such as opening or a short circuit occurs in the electrode film 34.

When the electrode film 34 is formed of a metal such as tungsten, due to a difference in stress occurring in the electrode film 34 in the X-direction and Y-direction, the electrode film 34 is likely to be bent and deformed. There is a fear that due to the deformation of the electrode film 34, the stacked body 32 is deformed, and a pattern formed in the stacked body 32 is collapsed.

In the embodiment, the support member 55 is provided in the region R1 of the through-via region Rv, and therefore, the deformation of the stacked body 32 is suppressed.

According to the embodiment, a semiconductor memory device having high reliability is provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a circuit portion provided on the substrate, and including an interconnect layer;
a stacked body provided on the circuit portion, and including a plurality of electrode films which is separately stacked each other and extends in a first direction along an upper surface of the substrate;
at least one columnar member in contact with the interconnect layer, and including a contact extending in a stacking direction of the plurality of electrode films in the stacked body;
a device isolation portion provided in the stacked body and extending in the first direction and the stacking direction; and
at least one first support member provided in the stacked body, extending in the stacking direction, and located on the device isolation portion in a second direction crossing the first direction and along the upper surface of the substrate.

2. The device according to claim 1, wherein the first support member is located on one side surface in the second direction of the device isolation portion.

3. The device according to claim 1, wherein
a plurality of first support members is provided along the first direction, and
the first support members are located on both side surfaces in the second direction of the device isolation portion.

4. The device according to claim 1, further comprising:
a plurality of second support members provided in the stacked body and extending in the stacking direction,
wherein the first support member is located in a region surrounded by the columnar member, the device isolation portion, and the plurality of second support members.

5. The device according to claim 1, wherein the first support member contains an insulating material.

6. The device according to claim 1, wherein the first support member contains silicon oxide.

7. The device according to claim 1, wherein the first support member contains polysilicon.

8. The device according to claim 1, wherein a shape of the first support member is a columnar shape in which an arc is formed in a part.

9. The device according to claim 1, wherein a shape of the first support member is a prismatic column.

10. The device according to claim 1, further comprising:
a first interconnect provided between the circuit portion and the stacked body,
wherein a lower end of the first support member is in contact with the first interconnect.

11. The device according to claim 1, wherein
a plurality of columnar members is provided along the second direction, and
the first support member is located between the columnar members.

12. The device according to claim 11, wherein
a plurality of first support members is provided along the first direction, and
the plurality of columnar members is disposed along the first direction.

13. The device according to claim 1, further comprising:
an insulating member provided in the stacked body and extending in the first direction,
wherein the first support member is located between the device isolation portion and the insulating member in the second direction.

14. The device according to claim 1, further comprising:
a semiconductor pillar provided in the stacked body and extending in the stacking direction, and
wherein the columnar member and the first support member are located in a second region adjacent in the first direction to a first region in which the semiconductor pillar is located.

15. A semiconductor memory device comprising:
a substrate;
a circuit portion provided on the substrate, and including an interconnect layer;
a stacked body provided on the circuit portion, and includes a plurality of electrode films which is separately stacked each other and extends in a first direction along an upper surface of the substrate;
a plurality of columnar members in contact with the interconnect layer, and disposed along the first direction, each of the plurality of the columnar members including a contact extending in a stacking direction of the plurality of electrode films in the stacked body;
a device isolation portion provided in the stacked body and extending in the first direction and the stacking direction; and
a plurality of first support members provided in the stacked body, extending in the stacking direction, and disposed along the first direction,
the plurality of first support members being located between the plurality of columnar members and the device isolation portion in a second direction crossing the first direction and along the upper surface of the substrate, and located on the device isolation portion.

16. The device according to claim 15, wherein the plurality of first support members is located on one side surface in the second direction of the device isolation portion.

17. The device according to claim 15, wherein the plurality of first support members is located on both side surfaces in the second direction of the device isolation portion.

18. The device according to claim 15, further comprising:
a plurality of second support members provided in the stacked body and extending in the stacking direction, and
wherein one of the plurality of first support members is located in a region surrounded by one of the plurality of columnar members, the device isolation portion, and the plurality of second support members.

19. The device according to claim 15, wherein the plurality of first support members contains an insulating material.

20. The device according to claim 15, wherein the plurality of first support members contains silicon oxide.
